(19) United States
(12) Patent Application Publication
(10) Pub. No.: US 2026/0371571 A1
(43) Pub. Date: Nov. 19, 2026

(54) SEMICONDUCTOR DEVICE AND METHOD OF FABRICATING THE SAME

(71) Applicant: Fujian Jinhua Integrated Circuit Co., Ltd., Quanzhou City (CN)

(72) Inventors: Peiyu Xu, Quanzhou City (CN); JIANSHAN WU, Quanzhou City (CN)

(73) Assignee: Fujian Jinhua Integrated Circuit Co., Ltd., Quanzhou City (CN)

(21) Appl. No.: 19/641,507

(22) Filed: Apr. 7, 2026

(30) Foreign Application Priority Data
Apr. 11, 2025 (CN) 202510457397.5

(51) Int. Cl. H10B 12/00

(52) U.S. Cl. CPC H10B 12/485; H10B 12/482; H10B 12/50

(57) ABSTRACT

The present disclosure provides a semiconductor device and a fabricating method thereof, including a substrate, bit line structures, plug structures, spacer structures, and of conductive pads. The bit line structures and the plug structures are alternately disposed on the substrate, further including a first bit line structure and a second bit line structure. The spacer structures are respectively disposed between each bit line structure and each plug structure, further including a first spacer structure disposed on a sidewall of the first bit line structure, and a second spacer structure disposed on a sidewall of the second bit line structure. The conductive pads are disposed on the bit line structures and the plug structures. The first spacer structure partially overlays and contacts a top surface of the first bit line structure, and a corresponding one of the conductive pads overlays and contacts a top surface of the second bit line structure.

### CROSS REFERENCE TO RELATED APPLICATION

This application claims the benefit of Chinese Patent Application No. 202510457397.5 filed on Apr. 11, 2025, which is incorporated herein by reference.

### BACKGROUND OF THE INVENTION

### 1. Field of the Invention

The present disclosure generally relates to a semiconductor device and a method of fabricating the same, and more particularly to a semiconductor device having a gate structure and a bit line structure, and a method of fabricating the same.

### 2. Description of the Prior Art

With the trend of miniaturization of various electronic products, semiconductor devices must be designed to meet the requirements of high integration and high density. For a dynamic random access memory (DRAM) with a trench gate structure, due to its advantage of having enlarged carrier channel length in common semiconductor substrate area so as to reduce current leakage in the capacitor structure, it has gradually replaced dynamic random access memory devices with planar gate structures under current development trend. Generally, a dynamic random access memory with a trench gate structure is an array area formed by a large number of memory cells for data storage. Each memory cell can be composed of transistor components and capacitor components in series to receive voltage data from word lines (WL) and bit lines (BL). With the increasing product requirements, higher and higher density of memory cells in the array area is also required, resulting in increasing difficulty and complexity in related manufacturing processes and designs. Therefore, conventional technologies or structures need to be improved to enhance efficiency and reliability of related memory devices.

### SUMMARY OF THE INVENTION

An object of the present disclosure is to provide a semiconductor device, where various spacer structures are disposed on sidewalls of bit line structures, so that, a bit line structure disposed within a peripheral region is allowable to effectively isolate other components disposed adjacent thereto through the spacer structure disposed on the sidewall of the bit line structure, and also, to maintain the integrity of components disposed within the cell region. Thus, the semiconductor device of the present disclosure will therefore gain improved structure and functions, so as to achieve better operating performance.

An object of the present disclosure is to provide a method of fabricating a semiconductor device, in which various spacer structures are formed on sidewalls of bit line structures under a simplified process flow, so that, a bit line structure formed within a peripheral region is allowable to effectively isolate other components formed adjacent thereto through the spacer structure disposed on the sidewall of the bit line structure, and also, to maintain the integrity of elements within the cell region. Thus, the semiconductor device formed accordingly in the present disclosure enables to obtain improved structure and functions, so as to gain better operating performance.

For achieving the above-described object, one embodiment of the present disclosure provides a semiconductor device including a substrate, a plurality of bit line structures and a plurality of plug structures, a plurality of spacer structures, and a plurality of conductive pads. The plurality of bit line structures and the plurality of plug structures are alternately disposed on the substrate, including at least one first bit line structure and at least one second bit line structure. The plurality of spacer structures is respectively disposed between each of the plurality of bit line structures and each of the plurality of plug structures, including a first spacer structure disposed on a sidewall of the at least one first bit line structure, and a second spacer structure disposed on a sidewall of the at least one second bit line structure. The plurality of conductive pads is disposed on the plurality of bit line structures and the plurality of plug structures. The first spacer structure partially overlays and directly contacts a top surface of the at least one first bit line structure, and a corresponding one of the plurality of conductive pads overlays and contacts a top surface of the at least one second bit line structure.

For achieving the above-described object, one embodiment of the present disclosure provides another semiconductor device including a substrate, a first bit line structure, a first plug, a second plug structure and a spacer layer. The first bit line structure is disposed on the substrate. The first spacer structure is disposed on two opposite sidewalls of the first bit line structure, at least partially overlaying a top surface of the first bit line structure. The first plug is disposed at a side of the first bit line structure, wherein a bottom surface of the first plug is higher than the substrate, and a top surface of the first plug is higher than the first bit line structure. The second plug structure is disposed at another side of the first bit line structure, wherein a bottom surface of the second plug is lower than the substrate, and a top surface of the second plug is lower than the second bit line structure. The first spacer structure includes a spacer layer disposed on a top surface of the second plug and overlaying a sidewall of the first spacer structure.

For achieving the above-described object, one embodiment of the present disclosure provides a fabricating method of a semiconductor device including the following steps. A substrate is provided, and a plurality of bit line structures on the substrate are formed on the substrate, including at least one first bit line structure and at least one second bit line structure. A spacer material layer is formed on the substrate, overlaying the at least one first bit line structure and the at least one second bit line structure. A sacrificial layer is formed between the plurality of bit line structures. An etching process is performed through a mask layer, removing the spacer material layer formed on a top surface of the at least one second bit line structure and a portion of the sacrificial layer, to remain the spacer material layer formed on a top surface of the at least one first bit line structure. A plurality of plug structures is formed on the substrate. A plurality of conductive pads is formed on the plurality of bit line structures and the plurality of plug structures, wherein at least one of the plurality of conductive pads overlays and contacts a top surface of the at least one second bit line structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIGS. 1-3 are schematic diagrams of a semiconductor device according to a first embodiment of the present disclosure, in which:

FIG. 1 illustrating a top view of a semiconductor device;

FIG. 2 illustrating cross-sectional views taken along cross lines A-A’ and B-B’ in FIG. 1; and

FIG. 3 illustrating cross-sectional views taken along cross lines C-C’ and D-D’ in FIG. 1.

FIGS. 4-11 are schematic diagrams of a semiconductor device according to a preferable embodiment of the present disclosure, in which:

FIG. 4 illustrating a top view of a semiconductor device after forming gate structures;

FIG. 5 illustrating cross-sectional views taken along the cross lines A-A’ and B-B’ in FIG. 5;

FIG. 6 illustrating a top view of a semiconductor device after forming bit line structures;

FIG. 7 illustrating cross-sectional views taken along the cross lines A-A’ and B-B’ in FIG. 6;

FIG. 8 illustrating a cross-sectional view of a semiconductor device after forming a photoresist layer;

FIG. 9 illustrating a cross-sectional view of a semiconductor device after forming a first plug;

FIG. 10 illustrating a cross-sectional view of a semiconductor device after forming a second plug; and

FIG. 11 illustrating a cross-sectional view of a semiconductor device after forming spacer structures and conductive pads.

FIG. 12 a schematic diagram of a semiconductor device according to a second embodiment of the present disclosure.

FIG. 13 a schematic diagram of a semiconductor device according to a third embodiment of the present disclosure.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

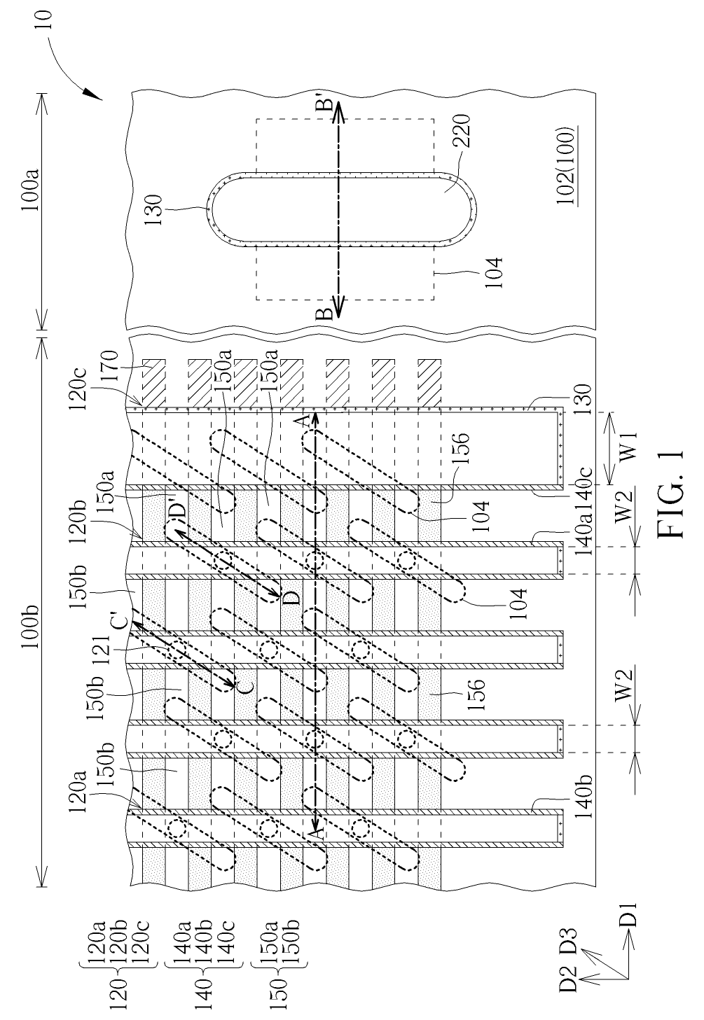

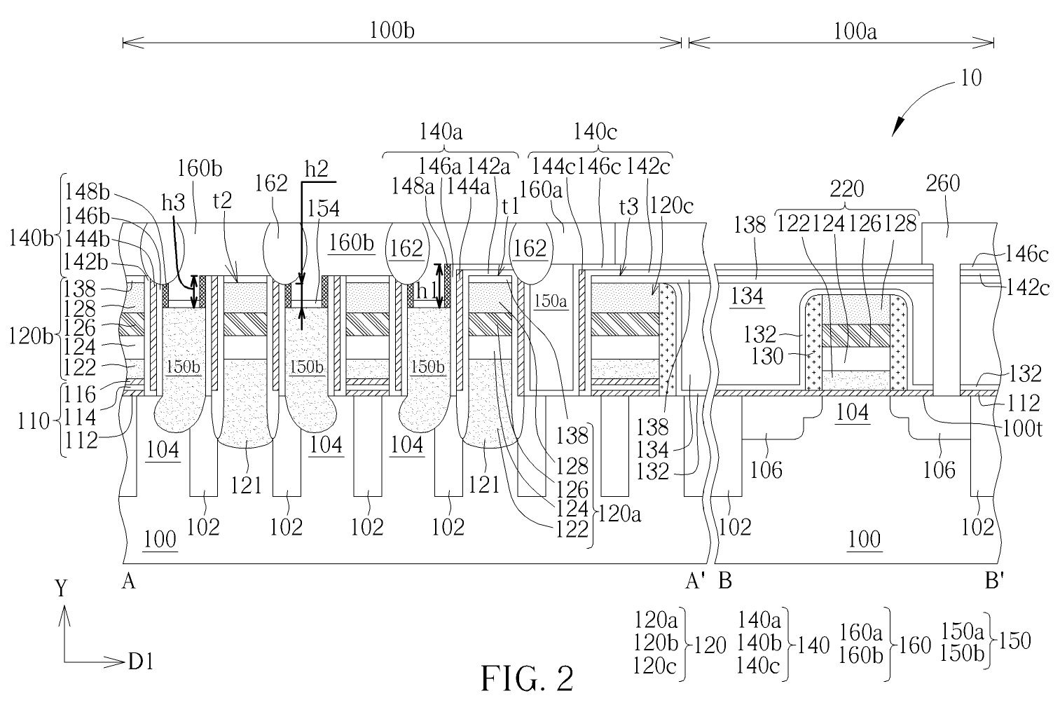

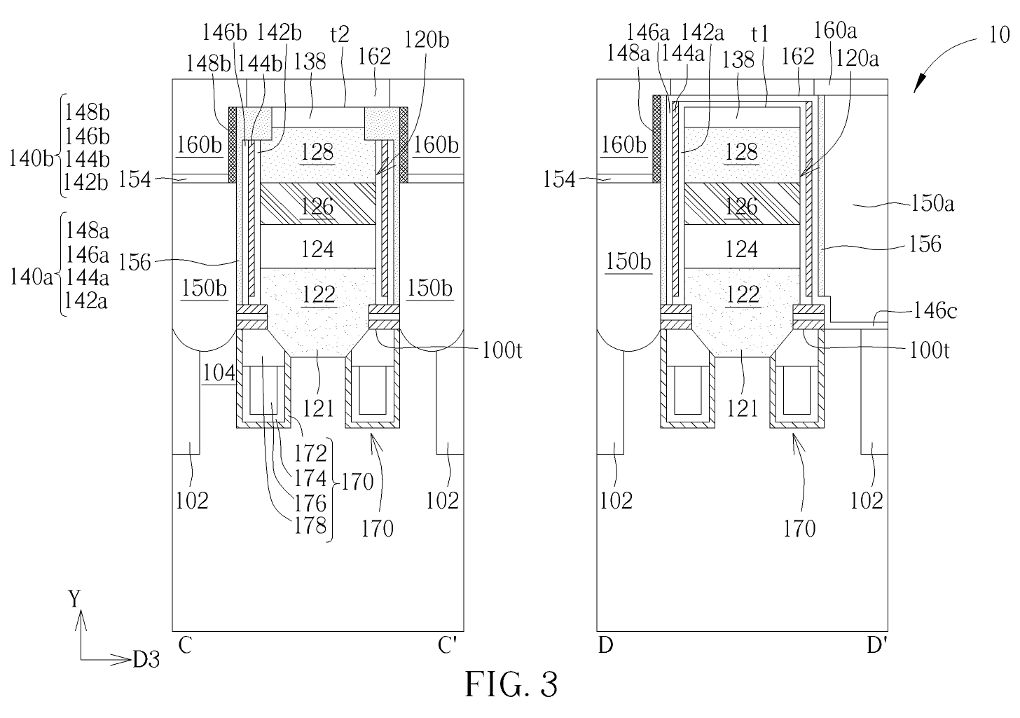

Please refer to FIGS. 1-3, which are schematic diagrams of a semiconductor device 10 according to a first embodiment of the present disclosure, with FIG. 1 illustration a top view of the semiconductor device 10, and with FIGS. 2 and 3 respectively illustrating a cross-sectional view of the semiconductor device 10. As shown in FIG. 1 and FIG. 2, the semiconductor device 10 includes a substrate 100, a plurality of bit line structures 120 and a plurality of plug structures 150 alternately disposed on the substrate, and a plurality of spacer structures 140 disposed between each of the bit line structures 120 and each of the plug structures 150, and a plurality of conductive pads 160 disposed on the bit line structures 120 and the plug structures 150. Although components disposed above the bit line structures 120, the spacer structure 140 and the plug structures 150 are not illustrated in FIG. 1, people skilled in the arts should easily realize the detailed position of the omitted component in FIG. 1 according to the cross-sectional views shown in FIGS. 2 and 3.

The substrate 100 for example includes, a silicon substrate, a silicon-containing substrate or a silicon-on-insulator substrate, and further includes a peripheral region 100a with a relatively low component integration degree, and a cell region with a relatively high component integration degree defined on the substrate. In one embodiment, the cell region 100b may be, but not necessarily, disposed adjacent to the peripheral region 100a. In addition, at least one shallow isolation structure 102 as shown in FIGS. 1 and 2 is disposed within the substrate 100, to define a plurality of active areas 104 also within the substrate 100. The bit line structures 120 includes at least one first bit line structures 120a and at least one second bit line structure 120b, both within the cell region 100b, and the spacer structure 140 includes a first spacer structure 140a disposed on a sidewall of the at least one first bit line structure 120a, and a second spacer structure 140b disposed on a sidewall of the at least one second bit line structure 120b. It is noted that the first spacer structure 140a further covers and directly contacts a portion of a top surface t1 of the at least one first bit line 120a, and a corresponding one of the conductive pads 160b overlays and directly contacts a top surface t2 of the at least one second bit line structure 120b. Accordingly, through arranging the first spacer structure 140a and the second spacer structure 140b with different stacking structures on the sidewalls of the at least one first bit line structure 120a and the at least one second bit line structure 120b, the at least one first bit line structure 120a disposed adjacent to the peripheral region 100a can be effectively electrically isolated from adjacent components (such as the corresponding conductive pads 160b disposed thereabove). Thus, the components disposed within the cell region 100b will therefore gain an improved structure, to improve the structural reliability and efficiency of the semiconductor device 10.

The bit line structures 120 further includes at least one third bit line structure 120c also disposed within the cell region 100b, and which for example includes a width W1 being relative greater than a width W2 of the at least one first bit line structure 120a or the at least one second bit line structure 120b, as shown in FIGS. 1 and 2, but not limited thereto. Precisely speaking, the bit line structures 120 for example includes a plurality of second bit line structures 120b, the at least one first bit line structures 120a and the at least one third bit line structure 120c within the cell region 100b, and which are respectively disposed on a dielectric layer 110 and each includes a semiconductor layer 122 (for example including a semiconductor material like doped polysilicon and doped amorphous silicon), a barrier layer 124 (for example including a conductive barrier material like titanium and/or titanium nitride, tantalum and/or tantalum oxide), a metal layer 126 (for example including a low-resistant metal material like copper, aluminum, tungsten), a cap layer 128 (for example including an insulating material like silicon nitride, silicon carbonitride or silicon oxynitride) and a capping layer 138 (for example including an insulating material like silicon nitride, silicon carbonitride or silicon oxynitride) sequentially stacked in a vertical direction Y from bottom to top. The at least one first bit line structure 120a and each second bit line structure 120b are respectively electrically connected to a corresponding one of the active areas 104 in the cell region 100b through at least bit line contact (BLC) 121 disposed underneath, with the at least bit line contact 121 being monolithic with the at least one first bit line structure 120a or each second bit line structure 120b, to further extend into the substrate 100. On the other hand, the at least one third bit line structure 120c does not include any contact disposed underneath, serving as a dummy bit line. In addition, the covering layer 138 of the at least one third bit line structure 120c further extends to overlay an insulating layer 134 disposed at a side of the at least one third bit line structure 120c, as shown in FIG. 2, but not limited thereto. In one embodiment, the dielectric layer 110 for example includes a silicon oxide layer 112, a silicon nitride layer 114 and a silicon oxide layer 116 stacked in sequence to obtain an oxide-nitride-oxide (ONO) structure, but not limited thereto.

The plug structures 150 includes a first plugs 150a disposed at a side of the at least one first bit line structure 120a, and a second plugs 150b disposed at a side of each of the second bit line structures 120b. The first plugs 150a has a bottom surface being higher than a top surface 100t of the substrate 100, and a top surface being higher than the top surface t1 of the at least one first bit line structure 120a. The second plugs 150b partially extends into the substrate 100, and which has a bottom surface being lower than the top surface 100t of the substrate, and a top surface being lower than the top surface t2 of each second bit line structure 120b. In one embodiment, the second plugs 150b includes a semiconductor material like doped polysilicon or doped amorphous silicon, or a low-resistant metal material like tungsten, aluminum or copper, for electrically connecting to active areas 104 within the cell region 100B, and the first plug 150a includes an insulating material like silicon oxide or silicon oxynitride, without electrically connecting to any component. Accordingly, each second plugs 150b will serve as a storage node contact (SC) of the semiconductor device 10, for receiving and transmitting voltage signals from the substrate 100 (for example from a source or drain of a transistor within the substrate), and the first plugs 150a is functioned like a dummy plug.

On the other hand, the conductive pads 160 are alternately arranged with a plurality of insulating spacer layers 162 disposed on the spacer structure 140 in the first direction D1, and which include conductive pads 160a and 160b respectively disposed on the first plugs 150a and each second plugs 150b. The conductive pad 160a is disposed both on the first plugs 150a and the at least one third bit line structure 120, and each conductive pad 160b is disposed both on one second plugs 150b and the at least one first bit line structure 120a, or disposed both on one second plugs 150b and one corresponding second bit line structure 120b. The conductive pad 160b simultaneously disposed on one second plugs 150b and the corresponding second bit line structure 120b overlays and directly contacts the covering layer 138 of the corresponding second bit line structure 120b, and the conductive pad 160b simultaneously disposed one second plugs 150b and the at least one first bit line structure 120a does not contact the covering layer 138 of the at least one first bit line structure 120a, as shown in FIG. 2. In one embodiment, each of the conductive pads 160 for example includes a low-resistant metal material like copper, aluminum, tungsten, and the insulating spacer layers 162 for example include an insulating material like silicon nitride or silicon carbonitride, but not limited thereto. Accordingly, each conductive pad 160b may be electrically connected to the corresponding second plugs 150b through a metal silicide layer 154 disposed underneath, and the conductive pad 150a directly contacts the first plug 150 being configured as the dummy plug.

The spacer structure 140 further includes a third spacer structure 140c disposed on a sidewall of the at least one third bit line structure 120c, such that, the first spacer structure 140a, the second spacer structure 140b, and the third spacer structure 140c are respectively disposed on the sidewalls extending in the second direction D2 of the at least one first bit line structure 120a, each second bit line structure 120b, and the at least one third bit line structure 120c, as shown in FIGS. 1 and 2. Precisely speaking, The first spacer structure 140a for example includes a first spacer layer 146a (including a material like silicon nitride or silicon carbonitride) covering at a single side of the sidewall and the top surface t1 of the at least one first bit line structure 120a, a spacer layer 144a (including a material like silicon oxide or silicon oxynitride) covering the whole sidewall of the at least one first bit line structure 120a, and a second spacer layer 142a (including a material like silicon nitride or silicon carbonitride) covering and contacting the whole sidewall and top surface t1 of the at least one first bit line structure 120a, and a third spacer layer 148a (including a material like silicon nitride or silicon carbonitride) disposed on the upper portion of the sidewall of the at least one first bit line structure 120a, with the third spacer layer 148a being disposed between the first spacer layer 146a and a corresponding one of the conductive pads 160b. The second spacer structure 140b for example includes a first spacer layer 146b (including a material like silicon nitride or silicon carbonitride), a spacer layer 144b (for example including a material like silicon oxide or silicon oxynitride), and a second spacer layer 142b (including a material like silicon nitride or silicon carbonitride) covering the whole sidewall of each second bit line structure 120b, and a third spacer layer 148b (including a material like silicon nitride or silicon carbonitride) only disposed on the upper portion of the sidewall of each second bit line structure 120b, with the third spacer layer 148b being disposed between the first spacer layer 146b and a corresponding one of the conductive pads 160b.

The third spacer structure 140c includes a first spacer layer 146c (including a material like silicon nitride or silicon carbonitride) covering the whole sidewall and a top surfacet3 of the at least one third bit line structure 120c, a spacer layer 144c (including a material like silicon oxide or silicon oxynitride) covering the whole sidewall of the at least one third bit line structure 120c, and a second spacer layer 142c (including a material like silicon nitride or silicon carbonitride) covering the whole sidewall and the top surface t3 of the at least one third bit line structure 120c, as shown in FIG. 2, but not limited thereto. In one embodiment, the third spacer layer 148a of the first spacer structure 140a and the third spacer layer 148b of the second spacer structure 140b may be fabricated through the same process and both include the same material, and the first spacer layer 146a of the first spacer structure 140a, the first spacer layer 146b of the second spacer structure 140b and the first spacer layer 146c of the third spacer structure 140c may also be fabricated through the same process and all include the same material. In addition, the spacer layers 144a, 144b, 144cor the first spacer layers 146a, 146b, 146c of the above three spacer structures may be made of the same material through the same process, but not limited thereto.

It is noted that the second spacer layer 142a of the first spacer structure 140a covers two opposite sides of the sidewall and the top surface t1 of the at least one first bit line structure 120a in a continuous manner, to directly contact the two opposite sides of the sidewalls and the top surface t1 of at least one first bit line structure 120a, so that the conductive pad 160b disposed thereabove does not contact the top surface t1 of the at least one first bit line structure 120a. In addition, the first spacer layer 146a of the first spacer structure 140a covers the sidewall and the top surface t1 of the at least one first bit line structure 120a in a continuous manner, to partially contact the second spacer layer 142a disposed underneath. The second spacer layer 142c and the first spacer layer 146c of the third spacer structure 140c cover one side of the sidewall and the top surface t3 of the at least one third bit line structure 120c in a continuous manner, so that the conductive pad 160a disposed thereabove does not contact the top surface t3 of the at least one third bit line structure 120c. Also, the first spacer layer 146c of the third spacer structure 140c covers the top surface 100t of the substrate 100 between the at least one third bit line structure 120c and the at least one first bit line structure 120a, and another side of the sidewall of the at least one first bit line structure 120a. It is also noted that, the third spacer layers 148a, 148b of the first spacer structure 140a and the second spacer structure 140b are disposed on one corresponding second plugs 150b, so that the third spacer layer 148b of the second spacer structure 140b can partially contact the top surface of the corresponding second plugs 150b and a lateral surface of the conductive pad 160b disposed on the corresponding second plugs 150b. The third spacer layer 148a of the first spacer structure 140a is only disposed on the side of the sidewall of the at least one first bit line structure 120a, being adjacent to the second plugs 150b, without contacting any one of the insulating spacers 162. Accordingly, the third spacer layer 148a of the first spacer structure 140a will have a relatively large extending height h1 in the vertical direction Y. The third spacer layer 148b of the second spacer structure 140b is simultaneously disposed on two opposite sides of the sidewall of each second bit line structure 120b, with the third spacer layer 148b disposing on one side of the sidewall of each second bit line structure 120b contacting the insulating spacer 162 disposed thereabove, and having a relative smaller extending height h2 in the vertical direction Y. In this way, the third spacer layers 148a disposed on the two opposite sides of the sidewall of each second bit line structure 120b will have different extending heights h2 and h3 in the vertical direction Y, and both of the two extending heights h2 and h3 are smaller than the extending height h1.

Further in view of FIGS. 1 and 2, the semiconductor device 10 further includes a gate structure 220 disposed within the peripheral region 100, at a side of all of the bit line structures 120, and a gate spacer 130 (for example including a material like silicon nitride or silicon carbonitride) disposed on the sidewall of the gate structure 220. Precisely speaking, the gate structure 220 is for example disposed on the oxide layer 112, and also includes the semiconductor layer 122 (for example including a semiconductor material like doped polysilicon and doped amorphous silicon), the barrier layer 124 (for example including a conductive barrier material like titanium and/or titanium nitride, tantalum and/or tantalum oxide), the metal layer 126 (for example including a low-resistant metal material like copper, aluminum, tungsten) and the cap layer 128 (for example including an insulating material like silicon nitride, silicon carbonitride or silicon oxynitride) sequentially stacked in a vertical direction Y from bottom to top, but not limited thereto. In one embodiment, the formation of the gate structure 220 within the peripheral region 100a may be integrated with the fabricating process of the bit line structure 120 within the cell region 100b, so that the gate structure 220 and each bit line structure 120 will therefore include similar stacked layers and materials, but not limited thereto. It is noted that the gate spacer 130 is further disposed on another side of the sidewall of the at least one third bit line structure 120c, and which is covered by an etching stop layer 132 (for example including an insulating material like silicon nitride or silicon carbonitride), with the etching stop layer 132 being continuously extending from the another side of the sidewall of the at least one third bit line structure 120c and further covering two opposite sides of the sidewall and the top surface of the gate structure 220, as shown in FIG. 2.

As shown in FIG. 2, the insulating layer 134 and the covering layer 138 are also disposed within the peripheral region 100a, sequentially disposed on the etching stop layer 132 and entirely covering the gate structure 220. Also, the first spacer layer 146c and the second spacer layer 142c of the third spacer structure 140c are further disposed in the peripheral region 100a, sequentially overlaying the covering layer 138 and the gate structure 220. In another embodiment (not shown in the drawings), the first spacer layer (not shown in the drawings) and the second spacer layer (not shown in the drawings) of the third spacer structure may not overlay the covering layer 138 and the gate structure 220 within the peripheral region 100a optionally, but is not limited thereto. The semiconductor device 10 further includes a plug 260 disposed within the peripheral region 100a, and the plug 260 is disposed in the insulating layer 134 and the covering layer 138, with the plug 260 penetrating through the etching stop layer 132 and the oxide layer 112 to electrically connect to a doped region 106 at a side of the gate structure 220 in the substrate 100. In one embodiment, the formation of the plug 260 within the peripheral region 100a may be integrated with the fabricating process of the conductive pads 160 within the cell region 100b, so that the plug 260 will also include a low resistant metal material like tungsten, aluminum or copper.

As shown in FIGS. 1 and 3, the semiconductor device 10 further includes a plurality of word line structures 170 within the cell region 100b, and a plurality of storage node contact isolations (SCISO) 156 disposed on the substrate 100. The word line structures 170 are for example embedded in the substrate 100, with each of the word line structures 170 separately disposed in the second direction D2 to intersect the corresponding active areas 104 and shallow trench isolation 102. The SCISOs 156 are each disposed on each word line structure 170, with the SCISOs 156 being alternately arranged with the plug structures 160 in the second direction D2. Precisely speaking, each word line structure 170 includes a dielectric layer 172, a gate dielectric layer 174, a gate electrode 176 and a cap layer 178 stacked in sequence. A surface of the cap layer 178 is flushed with the top surface 100t of the substrate 100 and is covered by the dielectric layer 110, such that, each word line structure 170 will serve as a buried word line (BWL) of the semiconductor device 10 to receive or to transmit voltage signals from the substrate 100.

Further in view of FIG. 3, in the extending direction D3 (the cross line C-C' as shown in FIG. 3) of each active area 104, each second bit line structure 120b is disposed between two adjacent ones of the second plugs 150b, and the bit line contact 121 of each second bit line structure 120b is disposed between two adjacent word line structures 170 to directly contact the cap layer 178 of the two adjacent word line structures 170, with each second bit line structure 120b and the two adjacent ones of the second plugs 150b being isolated from each other through the second spacer structure 140b disposed therebetween. It is noted that, in the extending direction D3, the SCISO 156 is also disposed between the first spacer layer 146b and the third spacer layer 148b of the second spacer structure 140b, to partially cover the top surfaces of the first spacer layer 146b, the spacer layer 144b and the third spacer layer 148b of the second spacer structure 140b. Then, the top surface of the SCISO 156 can be flush with the top surface t2 of the second bit line structure 120b. In another direction (the cross-line D-D' as shown in FIG. 3), the at least one bit line structure 120a is disposed between the first plug 150a and one second plugs 150b adjacent thereto, and the bit line contacts 121 of the at least one first bit line structure 120a are also each disposed between two adjacent word line structures 170, to directly contact the cap layer 178 of the two adjacent word line structures 170, with the at least one first bit line structure 120a being isolated from the first plugs 150a and the second plugs 150b through the first spacer structure 140a. It is noted that, in the extending direction D3, the first spacer layer 146a of the first spacer structure 140a also covers one side of the sidewall and the top surface t1 of the at least one first bit line structure 120a, and the first spacer layer 146b of the third spacer structure 140c covers another side of the sidewall of the at least one first bit line structure 120a, and the SCISOs 156 are respectively disposed on the first spacer layer 146a of the first spacer structure 140a and the first spacer layer 146c of the third spacer structure 140c, being partially between the first spacer layer 146a and the third spacer layer 148a of the first spacer structure 140a. In other words, in the extending direction D3, the first spacer layer 146a of the first spacer structure 140a may be continuously disposed with the first spacer layer 146c of the third spacer structure 140c, so that the top surfaces of the SCISOs 156 disposed on the first spacer layer 146a of the first spacer structure 140a or the first spacer layer 146c of the third spacer structure 140c may be flushed with the top surface of the first spacer structure 140a or the top surface of the third spacer structure 140c, as shown in FIG. 3 (in the cross-line D-D’).

According to the semiconductor device 10 of the first embodiment, the first spacer structure 140 is disposed on the sidewall of the at least one bit line structure 120, with in the cell region 100b, with the first spacer structure 140 further covering the top surface t1 of the at least one bit line structure 120. In this way, through overlaying the whole sidewall and the top surface t1 by the first spacer layer 146a of the first spacer structure 140a, and/or through overlaying and contacting the whole sidewall and the top surface t1 of the at least one first bit line structure 120a by the second spacer layer 142a of the first spacer structure 140, the at least one first bit line structure enables to not in direction contact with the conductive pad 160b disposed thereabove. That is, the at least one first bit line structure 120a of the semiconductor device 10 is effectively isolated from adjacent components through the first spacer structure 140a, thereby reducing the chance that the at least one first bit line structure 120a within the specific region is short-circuited due to structural defects, and improving the structure reliability and the performance of the semiconductor device 10. Thus, the semiconductor device 10 of the present embodiment and a capacitor structure (not shown in the drawings) subsequently disposed within the cell region 100b is allowable to be configured as a dynamic random access memory (DRAM) device, with the capacitor structure and the transistor within the substrate 100 together forming a smallest memory cell of the DRAM device, for receiving voltage signals from the bit line structures 120 and the word line structures 170.

In order to make people skilled in the art of the present disclosure easily understand the semiconductor device 10 of the present disclosure, a fabricating method of the semiconductor device 10 in the present disclosure will be further described below.

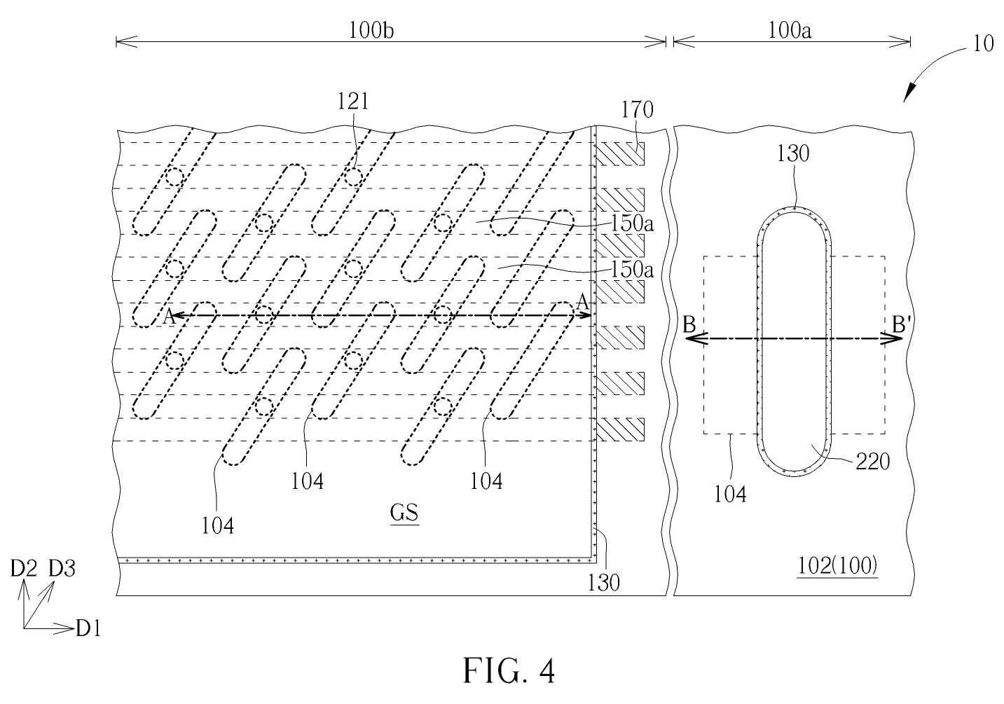

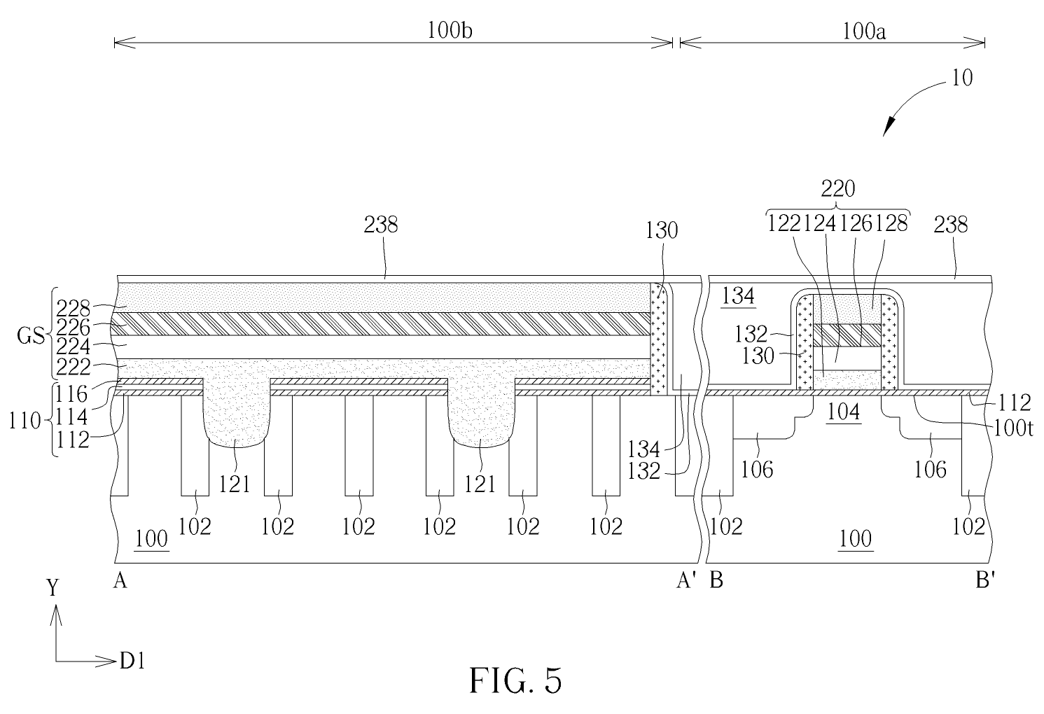

Please refer to FIGS. 4-11, which illustrate a method of fabricating a semiconductor device 10 according to a preferable embodiment of the present disclosure. As shown in FIGS. 4 and 5, the substrate 100 is provided, and the shallow trench isolation 102 is formed within the peripheral region 100a and the cell region 100b, to define the active areas 104. In one embodiment, the formation of the shallow trench isolation is carried out by firstly forming at least one shallow trench (not shown in the drawings) in the substrate 100 via an etching process, followed by filling at least one insulating material (such as including silicon oxide or silicon oxynitride) in the at least one shallow trench, to form the shallow trench isolation 102, but not limited thereto. Next, the gate structure 220 (including the semiconductor layer 122, the barrier layer 124, the metal layer 126 and the cap layer 128 stacked in sequence) and the bit line stacked structure GS (including the semiconductor layer 122, the barrier layer 124, a metal material layer 126 and the cap layer 128 stacked in sequence) are respectively formed within the peripheral region 100a and within cell region 100b of the substrate 100 through similar process. Precisely speaking, before forming the gate structure 220 and the bit line stacked structure GS, the silicon oxide layer 112 is formed in the peripheral region 100a of the substrate 100, and the dielectric layer 110 (including the silicon oxide layer 112, the silicon nitride layer 114 and the silicon oxide layer 116 formed in sequence) is formed in the cell region 100b. In an embodiment, the formations of the silicon oxide layer 112 within the peripheral region 100a and the dielectric layer 110 within the cell region 100b include but not limited to the following steps. Firstly, a first oxide material layer (not shown in the drawings), a nitride material layer (not shown in the drawings), and a second oxide material layer (not shown in the drawings) stacked in sequence are formed on the substrate 100, entirely overlaying the peripheral region 110a and the cell region 110a, and the second oxide material layer and the nitride material layer formed within the peripheral region 100a are then removed. Accordingly, the first oxide material layer remained in the peripheral region 100a becomes the silicon oxide layer 112. Otherwise, in another embodiment, the second oxide material layer, the nitride material layer and the first oxide material layer within the peripheral region 100a may also be completely removed and the silicon oxide layer 112 is additionally formed within the peripheral region 100a.

Then, a patterning process is performed through a mask layer (not shown in the drawings), to partially remove the second oxide material layer, the nitride material layer and the first oxide material layer formed within the cell region 100b, and a plurality of openings (not shown in the drawings) is formed with each opening partially exposing a portion of the substrate 100 to define the forming position of each bit line contact 121 as shown in FIGS. 1 and 2. Then, the mask layer is completely removed. Next, a semiconductor material layer (not shown in the drawings, for example including a semiconductor material like doped polysilicon or doped amorphous silicon), a barrier material layer (not shown in the drawings, for example including a conductive barrier material like titanium and/or titanium nitride, tantalum and/or tantalum oxide), a metal material layer (not shown in the drawings, for example including a low-resistant metal material like tungsten, aluminum or copper), and a capping material layer (not shown in the drawings, for example including an insulating material such as silicon nitride, silicon carbonitride or silicon oxynitride) stacked in sequence from bottom to top are simultaneously formed on the substrate 100, within the peripheral region 100a and the cell region 100b. A portion of the semiconductor material layer is filled in the openings. Another patterning process is performed through another mask layer, to partially remove the capping material layer, the metal material layer, the barrier material layer, the semiconductor material layer, and the first oxide material layer formed within the peripheral region 100a, forming the gate structure 220 and the silicon oxide layer 112 in the peripheral region 100a, and also, to partially remove the capping material layer, the metal material layer, the barrier material layer, the semiconductor material layer, and the dielectric layer 110 formed within the cell region 100b, forming a bit line stacked layer structure GS and the dielectric layer 110 in the cell region 100b, as shown in FIGS. 4 and 5. Then, the semiconductor material layer filled in the openings will therefore form the bit line contacts 121, and the another mask layer is completely removed.

As shown in FIG. 5, a deposition and etching-back process are formed simultaneously in the peripheral region 100a and the cell region 100b, and the gate spacer 130 is formed on the sidewalls of the gate structure 220 and the bit line stacked structure GS. Next, a deposition process is performed, to form an etching stop material layer (not shown in the drawing, for example including an insulating material like silicon nitride or silicon carbonitride) and an insulating material layer (not shown in the drawing, for example including an insulating material like silicon oxide or silicon oxynitride) entirely covering the gate structure 220 and the bit line stacked structure GS formed within the peripheral region 100a and the cell region 100b, and then, a planarization process is performed with the top surface of the bit line stacked structure GS as a stop layer, to partially remove the etching stop material layer and the insulating material layer, forming the etch stop layer 132 and the insulating layer 134 entirely covering the gate structure 220, the gate spacer 130 formed on the gate structure 220, and the sidewall of the bit line stacked structure GS. Then, the etch stop material layer and the insulating material layer are partially removed, and a covering material layer 238 entirely covering the insulating layer 134 and the bit line stacked structure GS is formed in the peripheral region 100a and the cell region 100b, for example including an insulating material like silicon nitride, silicon carbonitride or silicon oxynitride, but not limited thereto.

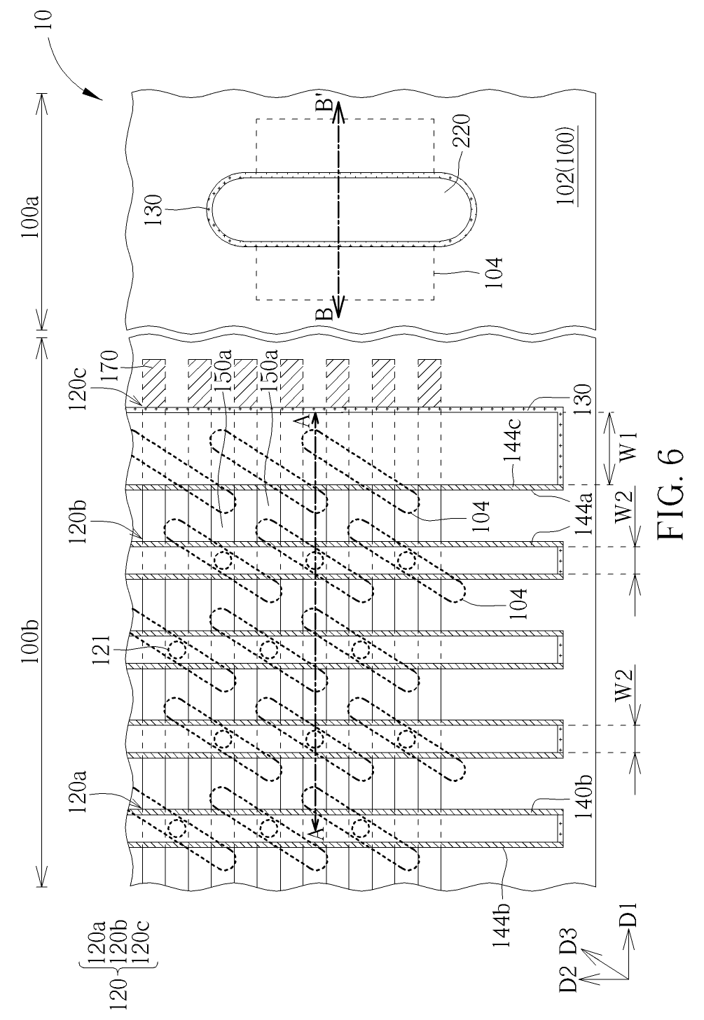

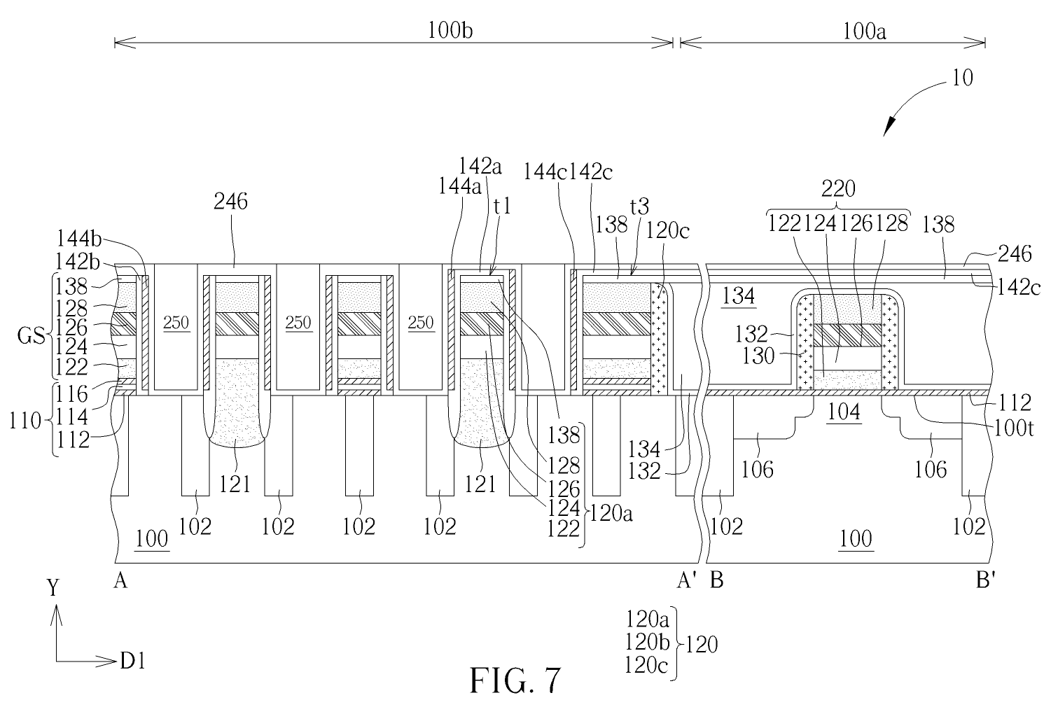

As shown in FIGS. 6 and 7, a patterning process is performed through another mask layer (not shown in the drawings), to pattern the capping material layer 238and the bit line stacked structure GS disposed underneath, within the cell region 100b, into the bit line structures 120, so that each bit line structure 120 will include the semiconductor layer 122, the barrier layer 124, the metal layer 126, the cap layer 128 and the capping layer 138 stacked in sequence in the vertical direction Y. The bit line structure 120 includes a plurality of second bit line structures 120b, and at least one first bit line structure 120a and at least one third bit line structure 120c adjacent to the peripheral region 100a, with the covering layer 138 of the at least one third bit line structure 120c partially extends to the insulating layer 134 formed at a side of the at least one third bit line structure 120c, but is not limited thereto. Then, after removing the another mask layer, at least one deposition and etch back process is performed, to form the second spacer layer 142a (including a material like silicon nitride or silicon carbonitride) covering and contacting the whole sidewall and the top surface t1 of the at least one first bit line structure 120a, and the spacer layer 144a (including a material like silicon oxide or silicon oxynitride) covering on the second spacer layer 142a, on the at least one first bit line structure 120a, to form a second spacer layer 142b (including a material like silicon nitride or silicon carbonitride) covering and contacting the whole sidewall and the top surface t1 of each second bit line structure 120b, and a spacer layer 144b (including a material like silicon oxide or silicon oxynitride) covering on the second spacer layer 142b, on each second bit line structure 120b, and to form the second spacer layer 142c (including a material like silicon nitride or silicon oxynitride) covering and contacting the whole sidewall of the at least one third bit line structure 120c, and the spacer layer 144c covering on the second spacer layer 142c, on the at least one third bit line structure 120c, at the same time. In addition the second spacer layer 142c is further formed within the peripheral region 100a, entirely covering the covering layer 138 and the gate structure 220. Then, a deposition and planarization process is performed within the cell region 100b, to sequentially forming a spacer material layer 246 (for example including a material like silicon nitride or silicon carbonitride) and a sacrificial layer 250 (for example including a material like silicon oxide or silicon oxynitride) conformally on the bit line structures 120 and the spacer layers 144a, 144b, 144c. The spacer material layer 246 is also formed within the peripheral region 100a, entirely covering the second spacer layer 142c, and the sacrificial layer 250 fills in the space between each of the bit line structures 120.

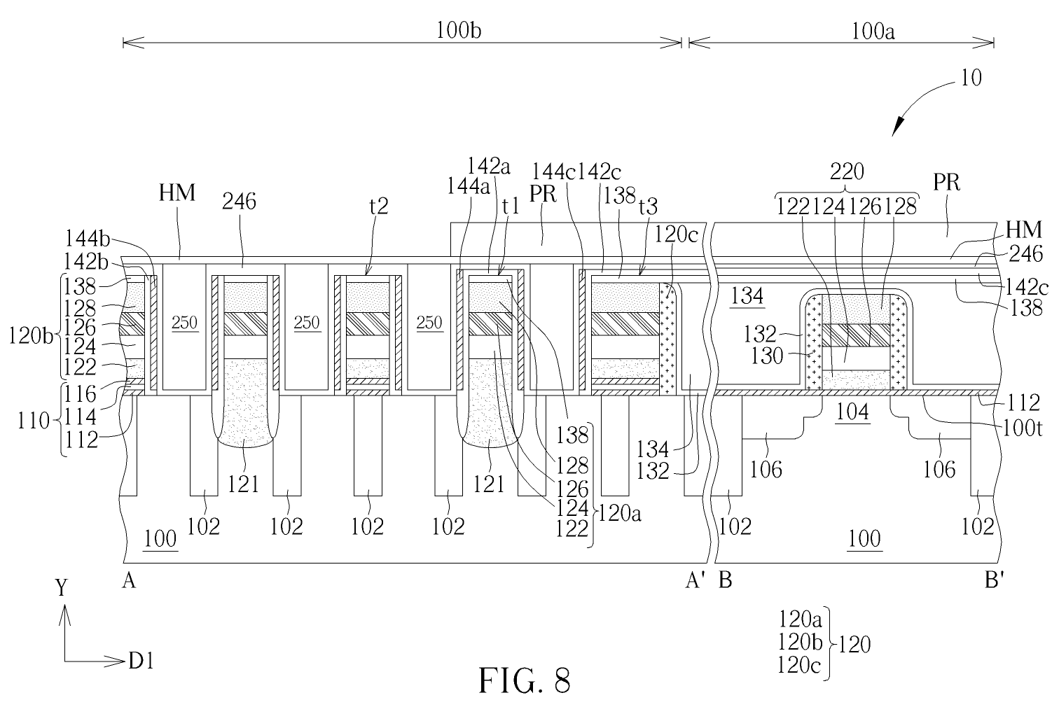

As shown in FIG. 8, a mask layer HM and a photoresist layer PR are sequentially formed on the sacrificial layer 252, with the mask layer HM entirely covering on the peripheral region 100a and the cell region 100b, and for example including a material like silicon oxide. The photoresist layer PR covers the peripheral region 100a, and the at least one first bit line structure 120a and the at least one third bit line structure 120c in the cell region 100b. That is, the photoresist layer PR covers the sacrificial layer 250 formed at one side of the at least one first bit line structure 120a, with the sacrificial layer 250 formed at the other side of the at least one first bit line structure 120a and the spacer material layer 246 formed on the top surface t2 of each second bit line structure 120b being exposed therefrom.

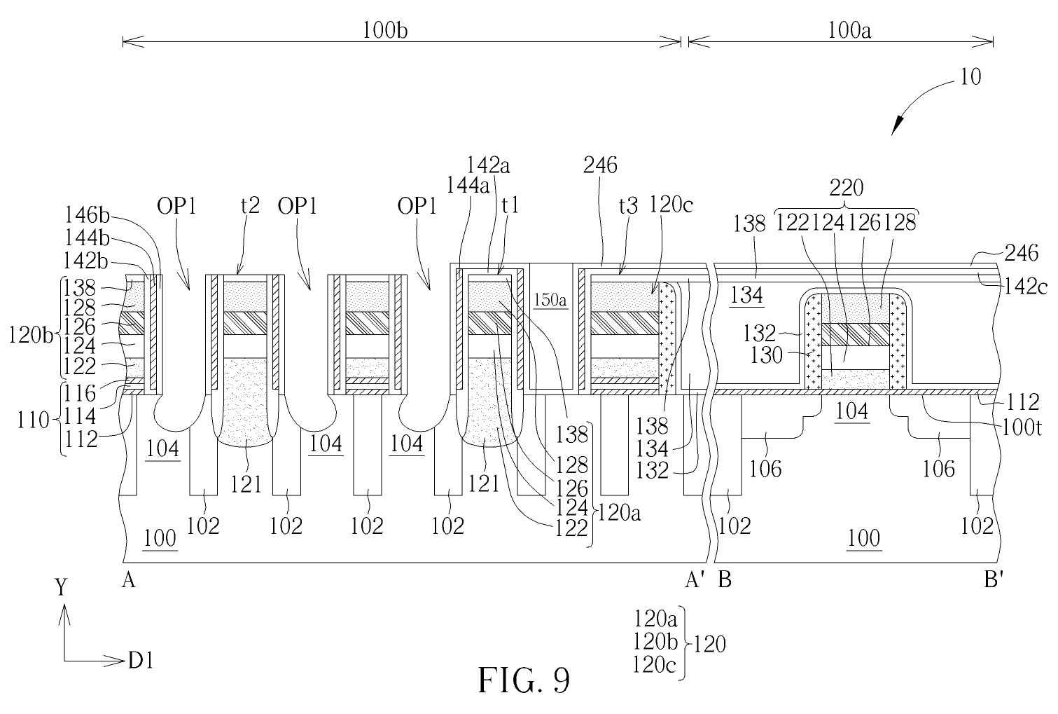

As shown in FIG. 9, at etching process is performed through the mask layer HM and the photoresist layer PR as shown in FIG. 8, to remove the mask layer HM, the sacrificial layer 250 and the spacer material layer 246 exposed from the photoresist layer PR, to form the first spacer layer 146b (including a material like silicon nitride or silicon carbonitride) on the spacer layer 144b of each second bit line structure 120b. Also, openings (not shown in the drawings) that exposes the top surface 100t of the substrate 100 are formed between each second bit line structure 120b, and between the at least one first bit line structure 120a and one corresponding second bit line structure 120b adjacent thereto. On the other hands, The spacer material layer 246 underlaying the photoresist layer PR still continuously covers the sidewalls and top surfaces t1, t3 of the at least one first bit line structure 120a and the at least one third bit line structure 120c, and the sacrificial layer 250 underlaying the photoresist layer PR is still remained between the at least one first bit line structure 120a and the at least one third bit line structure 120c, thereby forming the first plugs 150a serving as the dummy plug. Then, after completely removing the mask layer HM and the photoresist layer PR, another etching process is performed through the first spacer layer 146b and the spacer material layer 246, to form a plurality plug holes OP1 by downwardly etching the substrate 100 (including the active areas 104 and the shallow trench isolation 102) from the openings.

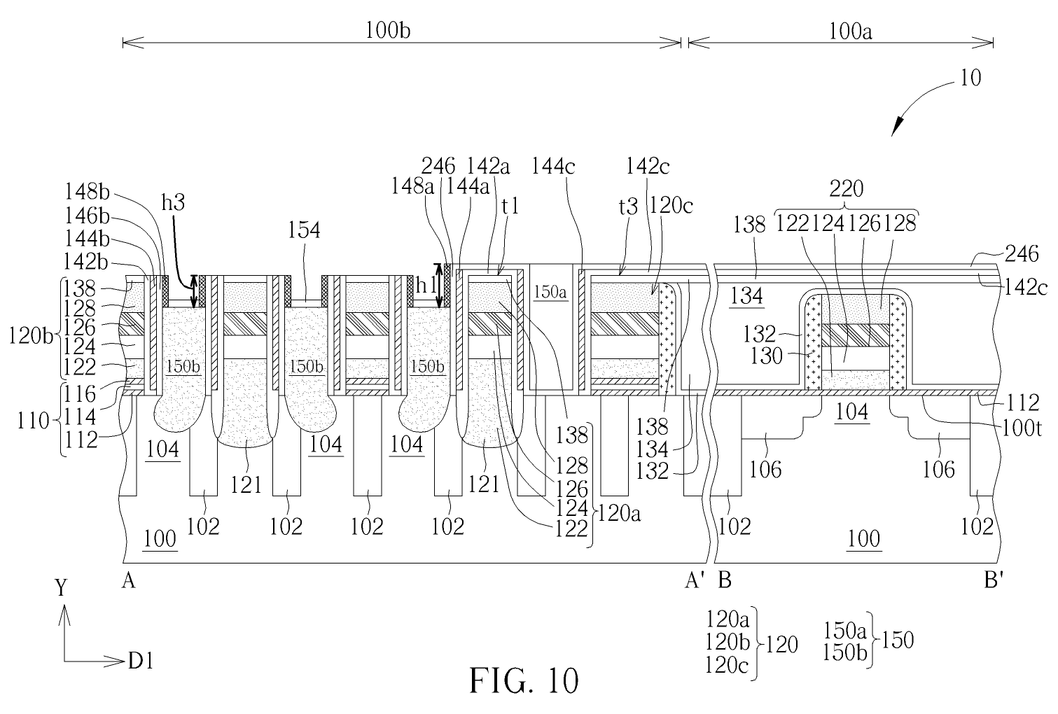

As shown in FIG. 10, a deposition process and etching-back process is performed, filling a semiconductor material such as doped polysilicon and doped amorphous silicon or a low-resistant metal material such as tungsten, aluminum or copper in the plug holes to form the second plugs 150b. The second plugs 150b formed accordingly each partially extends into the substrate 100, so as to obtain a bottom surface being lower than the top surface 100t of the substrate 100, and a top surface being lower than the top surface of the first plugs 150a or the top surface t2 of each second bit line structure 120b. Thus, the first plugs 150a and the second plugs 150b together form the plug structure 150 of the semiconductor device 10 as shown in FIGS. 1 and 2. Next, a deposition process and etching-back process is further performed, the third spacer layer 148b and the third spacer layer 148a (including a material like silicon nitride or silicon carbonitride) are formed on the upper portion of the sidewall of each plug hole OP1, on each second plugs 150b respectively. It is noted that since the first plugs 150a and one of the second plugs 150b are respectively formed on two opposite sides of the at least one first bit line structure 120a, the third spacer layer 148a can only be formed at the side where the one of the second plugs 150b is formed, over the spacer material layer 246. In this way, the third spacer layer 148a will have a relatively larger extending height h1 in the vertical direction Y, and the third spacer layer 148b is formed on the first spacer layer 146b to have a relatively smaller extending height h3, but not limited thereto. Then, a metal silicide process is performed to form a silicide layer 154 on each of the second plugs 150b.

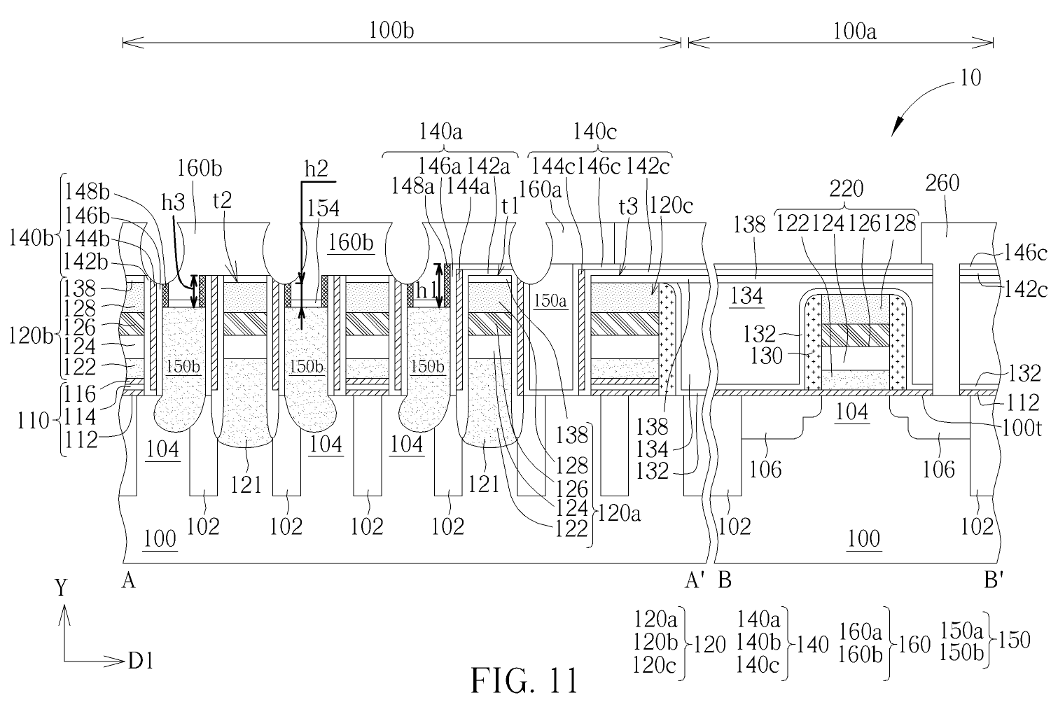

As shown in FIG. 11, a deposition process is formed both within the peripheral region 100a and the cell region 100b, to form a conductive material layer (not shown in the drawings, for example including a low-resistant metal material like tungsten, aluminum or copper) on the substrate 100, and a plurality of openings OP2 is formed in the conductive material layer through a mask layer (not shown in the drawings), and the mask layer is then removed. It is noted that through adjusting the etching condition of an etching process, such as the etching selectivity thereof, the spacer material layer 246 formed on the at least one first bit line structure 120a is also partially etched when the opening OP2 are formed, thereby forming the first spacer layer 146a (including a material like silicon nitride or silicon carbonitride) covering the sidewall and top surface t1 of the least one first bit line structure 120a, and forming the first spacer layer 146b (including a material like silicon nitride or silicon carbonitride) covering the another sidewall of the at least one first bit line structure 120a and the whole sidewall and top surface t3 of the at least one third bit line structure 120c. The first spacer layer 146c is also partially formed in the peripheral region 100a, entirely overlaying the second spacer layer 142c. In this way, the second spacer layer 142a, the spacer layer 144a, the first spacer layer 146a and the third spacer layer 148a sequentially formed on the at least one first bit line structure 120a will together form the first spacer structure 140a of the semiconductor device 10, and the second spacer layer 142c, the spacer layer 144c and the first spacer layer 146c sequentially formed on the at least one third bit line structure 120c will together form the third spacer structure 140c semiconductor device 10.

Furthermore, when forming the openings OP2, the third spacer layers 148b formed on one sidewall of each second bit line structure 120b are also partially etched, to obtain a height being smaller than the extending height h2 in the vertical direction Y. Accordingly, the third spacer layers 148a formed on the two opposite sidewalls of each second bit line structure 120b will have different extending heights h2 and h3 in the vertical direction Y, with each of the extending heights h2 and h3 being smaller than the extending height h1. In this way, the second spacer layer 142b, the spacer layer 144b, the first spacer layer 146b and the third spacer layer 148b sequentially formed on each second bit line structure 120b will together form the first spacer structure 140b of the semiconductor device 10. On the other hand, the conductive material layer are cut off into plurality of conductive pads 160, after forming the openings OP2, with the conductive pads 160 including the first conductive pad 160a and the second conductive pads 160b being respectively formed on the first plugs 150a and each second plugs 150b. The conductive pad 160a is formed over the first plugs 150a and the at least one third bit line structure 120c, to directly contact the first plugs 150a and the first spacer layer 146c formed on the at least one third bit line structure 120c. The conductive pads 160b are each formed above each of the second plugs 150b, and the at least one first bit line structure 120a or each second bit line structure 120b, with the conductive pad 160b being formed on the second plugs 150b and the at least one first bit line structure 120a simultaneously contacting the metal silicide layer 154 formed on the second plugs 150b and the first spacer layer 146a formed on the at least one first bit line structure 120a, and with each conductive pad 160b formed on the second plugs 150b and the second bit line structure 120b contacting the metal silicide layer 154 and the second plugs 150b.

Also, in one embodiment, before forming the conductive material layer, a plug hole (not shown in the drawings) may be optionally formed at one side of the gate structure 220 in the peripheral area 100a through the mask layer, with the plug hole simultaneously penetrating through the insulating layer 134, the covering layer 138, the etch stop layer 132 and the silicon oxide layer 112, to expose the doped region 106 formed within the substrate 100 at one side of the gate structure 220. Then, a plug 260 electrically connecting to the doped region is formed when forming the conductive pads 160, with the plug for example including a low-resistant metal material like tungsten, aluminum or copper, but not limited thereto. Otherwise, an additional deposition and patterning process may be performed either before or after the conductive pads 160 are formed, to form the plug 260. Subsequently, another deposition and etch back processes is performed on the substrate 100, to form the insulating spacers 162 as shown in FIGS. 1 and 2 in the openings OP2. Thus, the fabrication of the semiconductor device 10 in the preferred embodiment of the present disclosure is completed.

People skilled in the arts should easily understand that the fabricating method of the semiconductor device 10 in the present embodiment may further include forming a plurality the word line structures 170 and a plurality of the SCISO 156 in the cell region 100b. The word line structures 170 are formed within the substrate 100, and each separately extends in the second direction D2, to intersect the corresponding active areas 104 and the shallow trench isolation 102, and the SCISOs 156 are disposed on the word line structure 170, respectively. Through these performances, the semiconductor device 10 and a capacitor structure (not shown in the drawings) subsequently formed on the semiconductor device 10 are allowable to together form a DRAM device, with the capacitor structure and the transistor within the substrate 100 together forming a smallest memory cell of the DRAM device, for receiving voltage signals from the bit line structures 120 and the word line structures 170.

According to the fabricating method of the semiconductor device in the preferred embodiment, the first spacer structure 140a is formed on the sidewall of the at least one first bit line structure 120a adjacent to the cell region 100b, with the first spacer structure 140a further covering the top surface t1 of the at least one first bit line structure 120a. Through these performances, the spacer material layer 246 formed within the peripheral region 100a is simultaneously etched when the openings OP2 of the insulating spacers 162 are formed within the cell region 100b, to form the first spacer layers 140a and 146c of the first spacer structure 140a and the third spacer structure 140c without leading to additional steps. Also, through forming the first spacer layer 146a of the first spacer structure 140a to cover the whole sidewall and the top surface t1 of the at least one first bit line structure 120a, the conductive pad 160b will not directly contact the at least one first bit line structure 120a formed underneath, so that, the at least one first bit line structure 120a is electrically isolated from adjacent components in an effective manner, thereby reducing the possibility that the at least one first bit line structure 120a formed within in the specific region being short-circuited due to structural defects. Thus, the semiconductor device 10 being fabricated in the present embodiment will therefore gain an improved structure and performance.

People well known in the arts should easily realize the semiconductor device and the fabricating method thereof in the present disclosure is not limited to the aforementioned embodiment, and may further include other examples or variety. The following description will detail the different embodiments of the semiconductor device and the fabricating method thereof in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

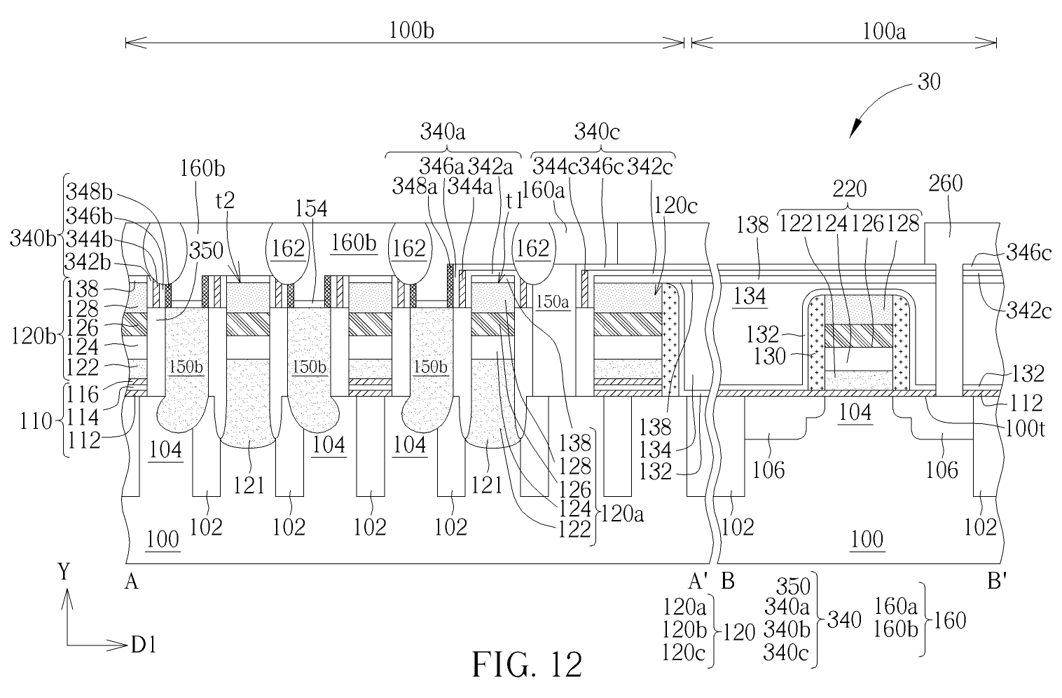

Please refer to FIG. 12, which illustrates a cross-sectional view of a semiconductor device 30 according to the second embodiment of the present disclosure. The structure of the semiconductor device 30 is substantially similar to the semiconductor device 10 in the aforementioned embodiment, the difference therebetween is mainly in that a spacer structure 340 of the semiconductor device 30 in the present embodiment further includes a spacer layers 350 additionally disposed on the sidewalls of the at least one first bit line structure 120a, the lower portion of the sidewalls of each second bit line structure 120b and the at least one third bit line structure 120c, and the sidewalls of each bit line contact 121. A first spacer structure 340a, a second spacer structure 340b, and a third spacer structure 340c in the present embodiment are respectively disposed on the upper portion of sidewalls of the at least one first bit line structure 120a, each second bit line structure 120b, and the at least one third bit line structure 120c, on the spacer layer 350. In one embodiment, the spacer layer 350 includes a material like silicon oxide, silicon nitride, silicon carbonitride or silicon oxynitride, and preferably includes a material being different from that of the first spacer structure 340a, the second spacer structure 340b, and the third spacer structure 340c, but not limited thereto.

Precisely speaking, the first spacer structure 340a for example includes a second spacer layer 342a (including a material like silicon nitride or silicon carbonitride), a spacer layer 344a (including a material like silicon oxide or silicon oxynitride), a first spacer layer 346a (including a material like silicon nitride or silicon carbonitride) and a third spacer layer 348a (including a material like silicon nitride) stacked in sequence on the upper portion of the sidewall of the at least one first bit line structure 120a. The second spacer layer 342a overlays and directly contacts the upper portion of the sidewalls and top surface t1 of the at least one first bit line structure 120a, and the first spacer layer 346a overlays the upper portion of one side sidewall and top surface t1 of

the at least one first bit line structure 120a, to directly contact a portion of the second spacer layer 342a disposed underneath. The second spacer structure 340b includes, for example, a second spacer layer 342b (including silicon nitride, silicon carbonitride and other materials), a spacer layer 344b (including silicon oxide, silicon oxynitride and other materials), a first spacer layer 346b (including silicon nitride, silicon carbonitride and other materials) and a third spacer layer 348b (including silicon nitride, silicon carbonitride and other materials) The third spacer structure 340c includes a second spacer layer 342c (including silicon nitride, silicon carbonitride and other materials, for example), a spacer layer 344c (including silicon oxide, silicon oxynitride and other materials, for example) and a first spacer layer 346c (including silicon nitride, silicon carbonitride and other materials, for example) sequentially arranged on the sidewall of the upper half of at least one third bit line structure 120c. The second spacer structure 340b for example includes a second spacer layer 342b (including a material like silicon nitride or silicon carbonitride), a spacer layer 344b (including a material like silicon oxide or silicon oxynitride), a first spacer layer 346b (including a material like silicon nitride or silicon carbonitride) and a third spacer layer 348b (including a material like silicon nitride or silicon carbonitride) stacked in sequence on the upper portion of the sidewall of each second bit line structure 120b. The third spacer structure 340c includes a second spacer layer 342c (including a material like silicon nitride or silicon carbonitride), a spacer layer 344c (including a material like silicon oxide or silicon oxynitride) and a first spacer layer 346c (including a material like silicon nitride or silicon carbonitride) stacked in sequence on the upper portion of the sidewall of the at least one third bit line structure 120c. The first spacer layer 346c and the second spacer layer 342c of the third spacer structure 340c extends into the peripheral region 100a, sequentially covering the covering layer 138 and the gate structure 220.The second spacer layer 342c overlays and directly contacts the upper portion of the sidewall and top surface t3 of the at least one third bit line structure 120c, and the first spacer layer 346c overlays the upper portion of the sidewall and top surface t3 of the at least one third bit line structure 120c, to directly contact a portion of the second spacer layer 342c disposed underneath, as shown in FIG. 12, but not limited thereto.

Through these arrangements, the first spacer structure 340a of the present embodiment still partially overlays the top surface t1 of the at least one first bit line structure 120a, with the at least one first bit line structure 120a directly in contact with the first spacer structure 340a, without contacting the conductive pad 160 disposed thereabove. In this way, through arranging the first spacer structure 340a on the upper portion of the sidewall of the at least one first bit line structure 120a, the at least one first bit line structure 120a adjacent to the peripheral region 100a will be still effectively isolated from the adjacent components (such as the conductive pads 160b disposed thereabove), optimizing the structure of the components disposed in the cell region 100b, thereby improving the structural reliability and efficiency of the semiconductor device 30.

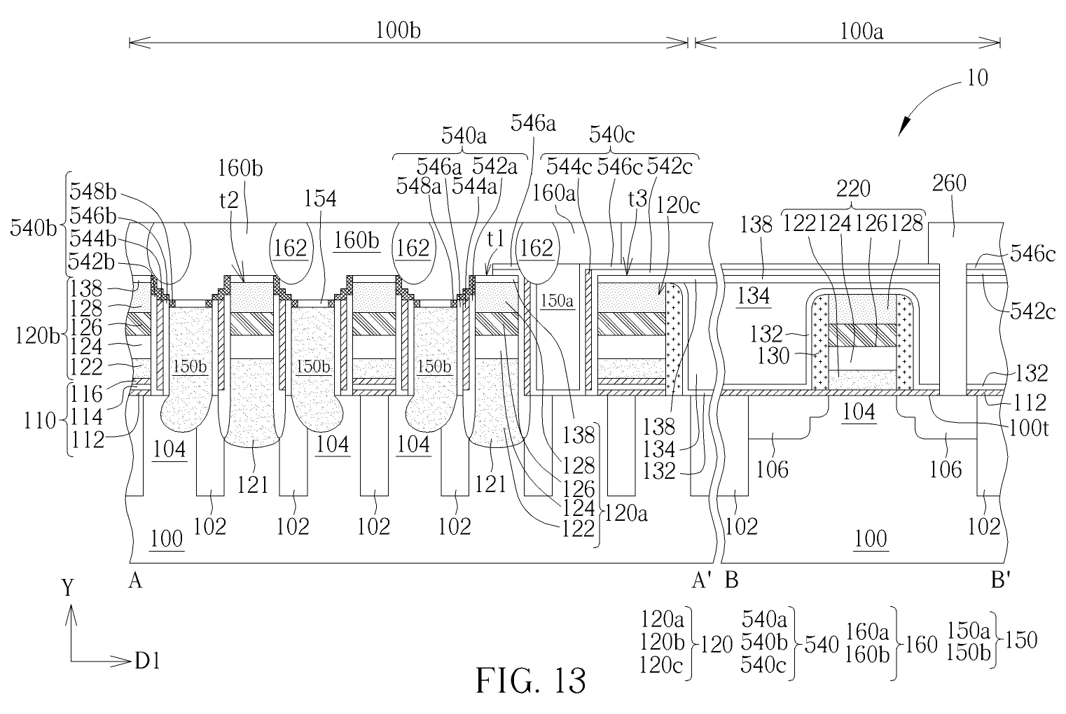

Please refer to FIG. 13, which illustrates a cross-sectional view of a semiconductor device 50 according to the third embodiment of the present disclosure. The structure of the semiconductor device 50 is substantially similar to the semiconductor device 10 in the aforementioned embodiment, the difference therebetween is mainly in that a spacer structure 540 of the semiconductor device 50 in the present embodiment includes a first spacer structure 540a, a second spacer structure 540b, and a third spacer structure 540c respectively disposed on the sidewall of the at least one first bit line structure 120a, each second bit line structure 120b, and the at least one third bit line structure 120c. The first spacer structure 540a partially overlays the top surface t1 of the at least one first bit line structure 120a, and the conductive pad 160b disposed over the at least one first bit line structure 120a partially contacts the covering layer 138 of the at least one first bit line structure 120a.

Precisely speaking, the first spacer structure 540a for example includes a second spacer layer 542a (for example including a material like silicon nitride or silicon carbonitride) disposed on two opposite sidewalls and a portion of the top surface t1 of the at least one first bit line structure 120a, a spacer layer 544a (for example including a material like silicon oxide or silicon oxynitride) disposed on the two opposite sidewalls of the at least one first bit line structure 120a, a first spacer layer 546a (for example including a material like silicon nitride or silicon carbonitride) disposed on one sidewall and the portion of the top surface t1 of the at least one first bit line structure 120a, and a third spacer layer 548a (for example including a material like silicon nitride or silicon carbonitride) disposed on the first spacer layer 546a.The second spacer layer 542a covers and directly contacts the two opposite sidewalls and the top surface t1 of the at least one first bit line structure 120a, and partially contacts the first spacer layer 546a disposed on the second spacer layer 542a, and the third spacer layer 548a is also partially disposed on the second spacer layer 542a and the first spacer layer 546a which are disposed on the top surface t1 of the at least one first bit line structure 120a. In addition, the second spacer layer 542a, the spacer layer 544a, and the first spacer layer 546a disposed adjacent to a side of the second plugs 150b each has a top surface being lower than the top surface t1 of the at least one first bit line structure 120a, so that, the third spacer layer 548a is partially disposed on the top surface and the sidewall of the second spacer layer 542a and the first spacer layer 546a adjacent to the side of the second plugs 150b, over the second spacer layer 542a and the first spacer layer 546a disposed on the top surface t1, thereby presenting in the discontinuous film as shown in FIG. 13.

The second spacer structure 540b of the present embodiment, for example includes a second spacer layer 542b (including a material like silicon nitride or silicon carbonitride), a spacer layer 544b (including a material like silicon oxide or silicon oxynitride), a first spacer layer 546b (including a material like silicon nitride or silicon carbonitride), and a third spacer layer 548b (including a material like silicon nitride or silicon carbonitride) stacked in sequence on two opposite sidewall of each of the second bit line structure 120b. Since the second spacer layer 542b, the first spacer layer 546b and the third spacer layer 548b of the second spacer structure 540b also have a top surface being lower than the top surface t2 of the second bit line structure 120b, the third spacer layer 548b is partially disposed on the adjacent second plugs 150b, and is partially disposed on the top surface and the sidewall of the second spacer layer 542b adjacent to a side of the second plugs 150b, and the first spacer layer 546b, thereby also presenting in the discontinuous film as shown in FIG. 13. The third spacer structure 540c of the present embodiment includes a second spacer layer 542c (for example including a material like silicon nitride or silicon carbonitride) simultaneously disposed on a single sidewall and the top surface t3 of the at least one third bit line structure 120c, a spacer layer 544c (for example including a material like silicon oxide or silicon oxynitride) disposed on the single sidewall of the at least one third bit line structure 120c, and a first spacer layer 546c (for example including a material like silicon nitride or silicon carbonitride) continuously covering on the single sidewall and the top surface t3 of the at least one third bit line structure 120c, the surface of the substrate 100 between the at least one third bit line structure 120c and the at least one first bit line structure 120a, and another sidewall of the at least one first bit line structure 120a. The second spacer layer 542c covers and directly contacts the single sidewall and the top surface t3 of the at least one third bit line structure 120c, and partially contacts the first spacer layer 546c disposed on the second spacer layer 542c. In addition, the first spacer layer 546c and the second spacer layer 542c of the third spacer structure 540c of the present embodiment are also disposed within the peripheral region 100a, sequentially covering the covering layer 138 and the whole structure of gate structure 220.

Through these arrangement, the first spacer structure 540a of the present embodiment still partially covers and contacts the top surface t1 of the at least one first bit line structure 120a, so that the conductive pad 160b disposed thereabove only partially contacts the top surface t1 of the at least one first bit line structure 120a, with the contact surface between the conductive pad 160b and the at least one first bit line structure 120a being lower than the top surface of the first spacer structure 540a.

In this way, through arranging the first spacer structure 540a on the sidewall of the at least one first bit line structure 120a, the at least one first bit line structure 120a disposed adjacent to the peripheral region 100a can still effectively isolate from adjacent components (such as the conductive pad 160b disposed on the at least one first bit line structure 120a), thereby optimizing the component structure disposed within the cell region 100b, and improving the structural reliability and efficiency of the semiconductor device 50.

Overall speaking, according to the semiconductor device and the manufacturing method thereof in the present disclosure, various spacer structures are disposed on sidewalls of bit line structures adjacent to the peripheral region, without introducing to additional steps, so that, the bit line structures disposed within the cell region is allowable to be effectively isolated from other components disposed adjacent the bit line structures, to maintain the integrity of components disposed within the cell region. Therefore, the semiconductor device of the present disclosure will therefore gain a more optimized structure and efficiency, to improve the overall operation performance thereby.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a plurality of bit line structures and a plurality of plug structures alternately disposed on the substrate, wherein the plurality of bit line structures comprises at least one first bit line structure and at least one second bit line structure;
a plurality of spacer structures, each disposed between each of the plurality of bit line structures and each of the plurality of plug structures, the plurality of spacer structures comprises a first spacer structure disposed on a sidewall of the at least one first bit line structure, and a second spacer structure disposed on a sidewall of the at least one second bit line structure; and
a plurality of conductive pads, disposed on the plurality of bit line structures and the plurality of plug structures;
wherein, the first spacer structure partially overlays and directly contacts a top surface of the at least one first bit line structure, and a corresponding one of the plurality of conductive pads overlays and directly contacts a top surface of the at least one second bit line structure.

2. The semiconductor device according to claim 1, wherein the first spacer structure and the second spacer structure each comprise a first spacer layer, the first spacer layer of the first spacer structure and the first spacer layer of the second spacer structure are in a same material, and the first spacer layer of the first spacer structure overlays the top surface of the at least one first bit line structure.

3. The semiconductor device according to claim 2, wherein the first spacer structure and the second spacer structure each further comprises a second spacer layer, the second spacer layer of the first spacer structure and the second spacer layer of the second spacer structure are in another same material, the second spacer layer of the first spacer structure directly contacts the top surface and the sidewall of the at least one first bit line structure, and the second spacer layer of the second spacer structure directly contacts the sidewall of the at least one second bit line structure.

4. The semiconductor device according to claim 3, wherein the first spacer layer of the first spacer structure further overlays the second spacer layer of the first spacer structure, and the corresponding one of the conductive pads overlays and directly contacts a top surface of the second spacer layer of the second spacer structure.

5. The semiconductor device according to claim 3, wherein the plurality of plug structures further comprises a first plug disposed at one side of the at least one first bit line structure, and a second plug disposed at one side of the at least one second bit line structure, the first plug comprises a bottom surface being higher than the substrate, and a top surface being higher than the at least one first bit line structure, and the second plug comprises a bottom surface being lower than the substrate, and a top surface being lower than the at least one second bit line structure.

6. The semiconductor device according to claim 5, wherein the first spacer structure and the second spacer structure each further comprises a third spacer layer, the third spacer layer of the first spacer structure and the third spacer layer of the second spacer structure are in another same material, the third spacer layer of the second spacer structure directly contacts the top surface of the second plug, and a lateral surface of the corresponding one of the plurality of conductive pads, and the third spacer layer of the first spacer structure is higher than the third spacer layer of the second spacer structure.

7. The semiconductor device according to claim 6, further comprising:
a plurality of insulating spacers, disposed on the plurality of spacer structures, wherein a corresponding one of the plurality of insulating spacers directly contacts the third spacer layer of the second spacer structure, and does not contact the third spacer layer of the first spacer structure.

8. The semiconductor device according to claim 6, wherein the third spacer layer of the first spacer structure disposed on the sidewall at only one side of the at least one bit line structure.

9. The semiconductor device according to claim 6, wherein the third spacer layer of the second spacer structure is disposed on the sidewall both at two opposite sides of the at least one second bit line structure, and the third spacer layer of the second spacer structure disposed at the two opposite sides of the at least one second bit line structure are in different heights in a vertical direction.

10. The semiconductor device according to claim 1, wherein the plurality of bit line structures each comprises a semiconductor layer, a metal layer and a covering layer stacked in sequence, and the first spacer structure overlays and directly contacts the covering layer of the at least one first bit line structure, and a corresponding one of the plurality of conductive pads overlays and directly contacts the covering layer of the at least one second bit line structure.

11. The semiconductor device according to claim 10, wherein another corresponding one of the plurality of conductive pads directly contacts the covering layer of the at least one first bit line structure, and a contact surface between the another corresponding one of the plurality of conductive pads and covering layer of the at least one first bit line structure is lower than a topmost surface of the first spacer structure.

12. The semiconductor device according to claim 9, wherein the third spacer layer of the first spacer structure overlaps and directly contacts sidewalls of the first spacer layer and the second spacer layer of the first spacer structure.

13. A semiconductor device, comprising:
a substrate;
a first bit line structure, disposed on the substrate;
a first spacer structure, disposed on two opposite sidewalls of the first bit line structure, the first spacer structure at least partially overlaying a top surface of the first bit line structure;
a first plug, disposed at a side of the first bit line structure, wherein a bottom surface of the first plug is higher than the substrate, and a top surface of the first plug is higher than the first bit line structure; and
a second plug structure, disposed at another side of the first bit line structure, wherein a bottom surface of the second plug is lower than the substrate, and a top surface of the second plug is lower than the first bit line structure;
wherein the first spacer structure comprise a spacer disposed on a top surface of the second plug and overlaying a sidewall of the first spacer structure.

14. The semiconductor device according to claim 13, further comprising a conductive pad disposed on the first bit line structure and the second plug, and the spacer contacts a sidewall of the conductive pad.

15. The semiconductor device according to claim 13, further comprising an insulating spacer disposed on the first plug.

16. The semiconductor device according to claim 14, wherein the conductive pad further contacts the top surface of the first bit line structure.

17. A method of fabricating a semiconductor device, comprising:
providing a substrate;
forming a plurality of bit line structures on the substrate, wherein the plurality of bit line structures comprises at least one first bit line structure and at least one second bit line structure;
forming a spacer material layer on the substrate, overlaying the at least one first bit line structure and the at least one second bit line structure;
forming a sacrificial layer between the plurality of bit line structures;
performing an etching process through a mask layer, removing a portion of the sacrificial layer and the spacer material layer formed on a top surface of the at least one second bit line structure, to remain the spacer material layer formed on a top surface of the at least one first bit line structure;
forming a plurality of plug structures on the substrate; and
forming a plurality of conductive pads on the plurality of bit line structures and the plurality of plug structures, wherein at least one of the plurality of conductive pads overlays and directly contacts the top surface of the at least one second bit line structure.

18. The method of fabricating a semiconductor device according to claim 17, wherein, after removing the mask layer, a first spacer layer is formed on sidewalls of the at least one first bit line structure and the at least one second bit line structure, and the first spacer layer formed on the at least one first bit line structure continuously covers the top surface and the sidewall of the at least one first bit line structure.

19. The method of fabricating a semiconductor device according to claim 18, before forming the spacer material layer, further comprising:
performing a deposition process and an etching-back process, forming a second spacer layer on the at least one first bit line structure and the at least one second bit line structure, wherein the second spacer layer formed on the at least one first bit line structure directly contacts the sidewall and the top surface of the at least one first bit line structure, and the second spacer layer formed on the at least one second bit line structure directly contacts the sidewall of the at least one second bit line structure.

20. The method of fabricating a semiconductor device according to claim 18, before forming the plurality of plug structures, further comprising:
performing another deposition process and an etching-back process, forming a third spacer layer on the at least one first bit line structure and the at least one second bit line structure, wherein, the third spacer layer formed on the at least one second bit line structure directly contacts a lateral surface of the at least one of the plurality of conductive pads, the third spacer layer formed on the at least one first bit line structure directly contacts the first spacer layer formed on the at least one first bit line structure, and a height of the third spacer layer formed on the at least one first bit line structure is higher than a height of the third spacer layer formed on the at least second bit line structure in a vertical direction.
